(19) United States
(12) Patent Application Publication
(10) Pub. No.: US 2009/0207286 A1
(43) Pub. Date: Aug. 20, 2009

(54) Colored photosensitive composition, and color filter array and solid image pickup device using the same

(76) Inventors: Yoshiko Miya, Kyoto (JP); Takuma Fujita, Osaka (JP); Taichi Natori, Tokyo (JP); Kensaku Maeda, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 12/320,342

(22) Filed: Jan. 23, 2009

(30) Foreign Application Priority Data
Jan. 24, 2008 (JP) 2008-014218

(51) Int. Cl. H04N 5/335; G03F 7/004; G03F 1/00

(52) U.S. Cl. 348/273; 430/270.1; 430/7

(57) ABSTRACT

An object of the present invention is to provide a colored photosensitive composition capable of forming a color filter array having improved spectral characteristics.

The colored photosensitive composition comprises a compound represented by the formula (I) or a salt thereof: wherein in the formula (I), Z¹ and Z² represent an oxygen or sulfur atom; R¹ to R⁴ represents a hydrogen atom, a saturated aliphatic hydrocarbon group (which may be substituted with a hydroxyl group), an aryl group, an aralkyl group, or an acyl group; and R⁵ to R¹² represents a hydrogen atom, a halogen atom, a (halogenated) saturated aliphatic hydrocarbon group, an alkoxyl group, a carboxyl group, a sulfo group, or an (N-substituted) sulfamoyl group, and at least one of R⁵ to R¹² is an N-substituted sulfamoyl group.

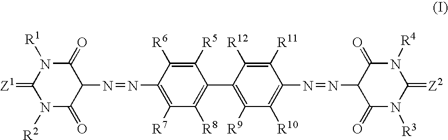

### BACKGROUND OF THE INVENTION

1. Field of the Invention

The present patent application claims priority under the Paris Convention based on Japanese Patent Application No. 2008-14218 (filed on Jan. 24, 2008), and the entire content of the aforementioned application is herein incorporated by reference.

The resent invention relates to a colored photosensitive composition which is useful to produce a color filter array to be formed on devices for coloration of solid image pickup devices (CCD, CMOS sensor, etc.).

2. Description of the Related Art

As a color filter array for coloring a solid image pickup device and a liquid crystal display device, for example, there is known a color filter array in which a red filter layer (R), a green filter layer (G), and a blue filter layer (B) are formed adjacently to each other on the same plane on devices. A plane pattern of each filter layer (R, G, B) of the color filter array is appropriately set. As the filter layer, a combination of complementary colors of yellow (Y), magenta (M), and cyan (C) may be employed, in addition to the combination of primary colors of red (R), green (G), and blue (B).

The color filter array is often produced by a color resist method in which colored photosensitive compositions corresponding to the respective filter layers are prepared and then patterning is conducted by sequentially exposing and developing these colored photosensitive compositions. As a coloring agent contained in the colored photosensitive composition, pigments are widely used. However, pigments are not dissolved in a developing solution to produce a developing residue and have a large particle diameter, thus leading to rough image quality, and are therefore disadvantageous for forming a fine pattern. Thus, use of a dye is proposed as the coloring agent which is dissolved in the developing solution (see, for example, Japanese Unexamined Patent Publication (Kokai) No. 2002-14220).

In order to form a red filter layer of a color filter array using a dye as a coloring agent (pigment), spectral characteristics are usually controlled by using a red coloring agent in combination with a yellow coloring agent. For example, Examples of Japanese Unexamined Patent Publication (Kokai) No. 2002-14220 describe that a transmittance at a wavelength of 535 nm of a red filter is controlled to 1% or less and also a transmittance at a wavelength of 650 nm of a red filter to 90% or more by using a specific xanthene-based pigment as a red coloring agent and using a pyrazoloneazo-based pigment (C.I. Solvent Orange 52, etc.) in combination with a pyridoneazo-based pigment (C.I. Solvent Yellow 162) as a yellow coloring agent.

It is required for a color filter array to have satisfactory light resistance, namely, burning is not caused by color fading of a coloring agent (pigment) under normal use. The colored filter array (particularly a red filter layer described in Examples of Japanese Unexamined Patent Publication (Kokai) No. 2002-14220) exhibits excellent light resistance, but leaves some room for improvement.

### SUMMARY OF THE INVENTION

Under these circumstances, the present invention has been made and an object thereof is to further improve light resistance of a color filter array (particularly a red filter layer) and to provide a colored photosensitive composition which enables the production of such a color filter array.

The present inventors have intensively studied so as to achieve the above object and found that light resistance of a color filter array can be further improved by using, as a yellow coloring agent to be used in combination with a red coloring agent, a azo compound represented by the formula (I) or a salt thereof (hereinafter may be abbreviated to an “azo compound (I)” including those in a salt form), and thus the present invention has been completed.

Namely, the colored photosensitive composition of the present invention has a feature that it comprises, as a coloring agent, at least one selected from a red coloring agent, and a compound represented by the formula (I) and a salt thereof. The colored photosensitive composition of the present invention comprises, in addition to the coloring agent, a photosensitive compound and an alkali-soluble resin.

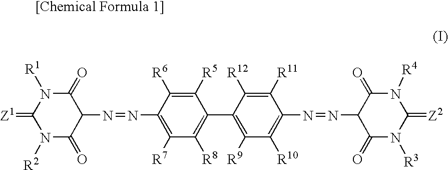

In the formula (I), Z¹ and Z² each independently represents an oxygen atom or a sulfur atom.

R¹ to R⁴ each independently represents a hydrogen atom, a C₁₋₁₀ saturated aliphatic hydrocarbon group, a C₁₋₁₀ saturated aliphatic hydrocarbon group substituted with a hydroxyl group, a C₁₋₁₀ saturated aliphatic hydrocarbon group substituted with a C₁₋₈ alkoxyl group, a C₁₋₁₀ saturated aliphatic hydrocarbon group substituted with a C₁₋₈ thioalkoxyl group, an aryl group having 6 to 20 carbon atoms, an aralkyl group having 7 to 20 carbon atoms, or an acyl group having 2 to 10 carbon atoms.

R⁵ to R¹² each independently represents a hydrogen atom, a halogen atom, a C₁₋₁₀ saturated aliphatic hydrocarbon group, a halogenated C₁₋₁₀ saturated aliphatic hydrocarbon group, a C₁₋₈ alkoxyl group, a carboxyl group, a sulfo group, a sulfamoyl group, or an N-substituted sulfamoyl group, and at least one of R⁵ to R¹² is an N-substituted sulfamoyl group.

As used herein, “C_{a-b}” means that the number of carbon atoms is a or more, and b or less.

The azo compound (I) is preferably an azo compound wherein at least one of R⁵ to R⁸, and at least one of R⁹ to R¹² (particularly at least one of R⁵ and R⁸, and at least one of R⁹ and R¹²) represent an N-substituted sulfamoyl group. The N-substituted sulfamoyl group in the azo compound (I) is preferably a —SO₂NHR¹³ group (in which R¹³ represents a C₁₋₁₀ saturated aliphatic hydrocarbon group, a C₁₋₁₀ saturated aliphatic hydrocarbon group substituted with a C₁₋₈ alkoxyl group, an aryl group having 6 to 20 carbon atoms, an aralkyl group having 7 to 20 carbon atoms, or an acyl group having 2 to 10 carbon atoms).

The azo compound (I) is also preferably an azo compound wherein at least one R¹ to R⁴ has 6 or more carbon atoms (particularly an azo compound wherein at least one of R¹ to R⁴ is an aryl group having 6 to 20 carbon atoms).

The red coloring agent to be used in the colored photosensitive composition of the present invention is preferably a xanthene-based pigment, and the photosensitive compound is preferably an oxime-based compound.

When the total of the coloring agent, the photosensitive compound, and the alkali-soluble resin is preferably 100 parts by mass, the content of the coloring agent is preferably from 5 to 80 parts by mass; the content of the photosensitive compound is preferably from 0.001 to 50 parts by mass; and the content of the alkali-soluble resin is preferably from 1 to 75 parts by mass. The colored photosensitive composition of the present invention may further comprise a curing agent.

The present invention also provides a color filter array formed by using the colored photosensitive composition, and a solid image pickup device and a camera system, each comprising the color filter array.

According to the present invention, light resistance of a color filter array is further improved by using, as a yellow coloring agent to be used in combination with a red coloring agent, an azo compound (I).

### BRIEF DESCRIPTION OF THE DRAWINGS

FIG. 1 is a partially enlarged schematic sectional view showing an example of a CCD image sensor.

FIG. 2 is a first view showing a method for producing the image sensor of FIG. 1.

FIG. 3 is a second view showing the method for producing the image sensor of FIG. 1.

FIG. 4 is a third view showing the method for producing the image sensor of FIG. 1.

FIG. 5 is a fourth view showing the method for producing the image sensor of FIG. 1.

FIG. 6 is a fifth view showing the method for producing the image sensor of FIG. 1.

FIG. 7 is a sixth view showing the method for producing the image sensor of FIG. 1.

FIG. 8 is a block diagram showing an example of a camera system.

### DESCRIPTION OF THE PREFERRED EMBODIMENTS

In the photosensitive composition of the present invention, the azo compound (I) to be used as a yellow coloring agent has a feature that it has a framework of barbituric acid (Z (namely Z¹, Z²)═O) and/or thiobarbituric acid (Z (namely, Z¹, Z²)═S) structures bonded to an azo group at both ends of a biphenyl skeleton. Barbituric acid and thiobarbituric acid moieties include, in addition to a keto type one represented by the formula (I), an enol type one. The use of the azo compound (I) having such a structure enables further improvement of light resistance of a color filter array as compared with a pyridoneazo-based pigment (C.I. Solvent Yellow 162 in Examples) described in Japanese Unexamined Patent Publication (Kokai) No. 2002-14220 (see Examples described hereinafter).

First, the formula (I) is described in detail. In the formula (I), Z¹ and Z² each independently represents an oxygen atom or a sulfur atom. Z¹ and Z² may be the same or different, and are preferably the same.

In the formula (I), R¹ to R⁴ each independently represents a hydrogen atom, a C₁₋₁₀ saturated aliphatic hydrocarbon group (including those in which a hydroxyl group, a C₁₋₈ alkoxyl group, or a C₁₋₈ thio alkoxyl group is bonded to the C₁₋₁₀ saturated aliphatic hydrocarbon group), an aryl group having 6 to 20 carbon atoms, an aralkyl group having 7 to 20 carbon atoms, or an acyl group having 2 to 10 carbon atoms.

The saturated aliphatic hydrocarbon group represented by R¹ to R⁴ may be linear, branched, or cyclic. The number of carbon atoms of a substituent is not included in the number of carbon atoms of the saturated aliphatic hydrocarbon group. The number of carbon atoms is usually from 1 to 10, preferably from 2 to 8, and more preferably from 3 to 6. Examples of the saturated aliphatic hydrocarbon group include a methyl group, an ethyl group, an n-propyl group, an isopropyl group, an n-butyl group, an isobutyl group, a sec-butyl group, a tert-butyl group, an ethylhexyl group (2-ethylhexyl group, etc.), a cyclopentyl group, a cyclohexyl group, and a cyclohexylalkyl group. As described above, the saturated aliphatic hydrocarbon group may be substituted with a substituent such as a hydroxyl group, a C₁₋₈ (preferably C₁₋₄) alkoxyl group, or a C₁₋₈ (preferably C₁₋₄) thioalkoxyl group. Examples of the substituted saturated aliphatic hydrocarbon group include a hydroxyethyl group (2-hydroxyethyl group, etc.), an ethoxyethyl group (2-ethoxyethyl group, etc.), an ethylhexyloxypropyl group (3-(2-ethylhexyloxy)propyl group, etc.), and a methylthiopropyl group (3-methylthiopropyl group, etc.).

The aryl group represented by R¹ to R⁴ may have no substituent, or may have a substituent such as a saturated aliphatic hydrocarbon group, an alkoxyl group, a carboxyl group, a sulfo group, or an ester group. The number of carbon atoms of the aryl group includes the number of carbon atoms of a substituent, and is usually from 6 to 20, and preferably from 6 to 10. Examples of the aryl group include non-substituted or substituted phenyl groups such as a phenyl group, a 2-, 3-, 4-methylphenyl group, a 2-, 3-, 4-methoxyphenyl group, a 2-, 3-, 4-sulfophenyl group, and an ethoxycarbonylphenyl group (4-(COOC₂H₅)Ph group, etc.).

The alkyl moiety of the aralkyl group (arylalkyl group) represented by R¹ to R⁴ may be either linear or branched. The number of carbon atoms of the aralkyl group includes the number of carbon atoms of a substituent, and is usually from 7 to 20, and preferably 7 to 10. The aralkyl group is typically a phenylalkyl group such as a benzyl group.

The acyl group represented by R¹ to R⁴ may have no substituent, or may have a substituent such as a saturated aliphatic hydrocarbon group or alkoxyl group bonded thereto. The number of carbon atoms of the acyl group includes the number of carbon atoms of the substituent and is usually from 2 to 10, and preferably from 6 to 10. Examples of the acyl group include an acetyl group, a benzoyl group, and a methoxybenzoyl group (p-methoxybenzoyl group, etc.).

In order to increase color density of the azo compound (I), it is recommended that a group having carbon atoms of 5 or less (preferably 3 or less) such as a methyl group or an ethyl group, or a hydrogen atom is selected as at least one (preferably all) of R¹ and R⁴.

In order to increase solubility (oil solubility) of the azo compound (I) in an organic solvent, it is preferred to select a group having 6 or more carbon atoms, particularly a substituted or unsubstituted aryl group (preferably a phenyl group) as at least one (preferably all) of R¹ and R⁴.

In the formula (I), R⁵ to R¹² each independently represents a hydrogen atom, a halogen atom (preferably a fluorine, chlorine or bromine atom), a C₁₋₁₀ saturated aliphatic hydrocarbon group (including those in which a halogen atom is bonded to the C₁₋₁₀ saturated aliphatic hydrocarbon group), a C₁₋₈ alkoxyl group, a carboxyl group, a sulfo group, a sulfamoyl group, or an N-substituted sulfamoyl group, and at least one of R⁵ to R¹² is an N-substituted sulfamoyl group.

Similar to the case of R¹ to R⁴, the saturated aliphatic hydrocarbon group represented by R⁵ to R¹² may be linear, branched, or cyclic, and the number of carbon atoms is usually from 1 to 10, preferably from 2 to 8, and more preferably from 3 to 6. Specific examples of the saturated aliphatic hydrocarbon group represented by R⁵ to R¹² are the same as those in the case of R¹ to R⁴. The saturated aliphatic hydrocarbon group represented by R⁵ to R¹² may be substituted with a halogen atom, and preferably a fluorine atom. Specific examples of the halogenated saturated aliphatic hydrocarbon group include a trifluoromethyl group.

The number of carbon atoms of the alkoxyl group represented by R⁵ to R¹² is usually from 1 to 8, and preferably from 1 to 4. Examples of the alkoxyl group include a methoxy group, an ethoxy group, an isopropoxy group, an n-propoxy group, an n-butoxy group, an isobutoxy group, a sec-butoxy group, and a tert-butoxy group.

The N-substituted sulfamoyl group represented by R⁵ to R¹² is, for example, an N-monosubstituted sulfamoyl group and can be represented by the formula: —SO₂NHR¹³. In the formula, R¹³ is a C₁₋₁₀ saturated aliphatic hydrocarbon group (including those in which a C₁₋₈ alkoxyl group is bonded to the C₁₋₁₀ saturated aliphatic hydrocarbon group), an aryl group having 6 to 20 carbon atoms, an aralkyl group having 7 to 20 carbon atoms, or an acyl group having 2 to 10 carbon atoms.

The saturated aliphatic hydrocarbon group represented by R¹³ may be linear, branched, or cyclic. The number of carbon atoms of the saturated aliphatic hydrocarbon group is usually from 1 to 10, and preferably from 6 to 10. Examples of the saturated aliphatic hydrocarbon group represented by R¹³ include a methyl group, an ethyl group, an n-propyl group, an isopropyl group, an n-butyl group, an isobutyl group, a sec-butyl group, a tert-butyl group, a methylbutyl group (1,1,3,3-tetramethylbutyl group, etc.), a methylhexyl group (1-methylhexyl group, 1,5-dimethylhexyl group, etc.), an ethylhexyl group (2-ethylhexyl group, etc.), a cyclopentyl group, a cyclohexyl group, a methylcyclohexyl group (2-methylcyclohexyl group, etc.), and a cyclohexylalkyl group. As described above, the saturated aliphatic hydrocarbon group represented by R¹³ may be substituted with a substituent such as a C₁₋₈ (preferably C₁₋₄) alkoxyl group. Examples of the substituted saturated aliphatic hydrocarbon group include a propoxypropyl group (3-(isopropoxy)propyl group, etc.).

The aryl group represented by R¹³ may have no substituent, or may have a substituent such as a saturated aliphatic hydrocarbon group or a hydroxyl group. The number of carbon atoms of the aryl group is usually from 6 to 20, and preferably from 6 to 10. Examples of the aryl group include substituted or non-substituted phenyl groups such as a phenyl group, a hydroxyphenyl group (4-hydroxyphenyl group, etc.), and a trifluoromethylphenyl group (4-trifluoromethylphenyl group, etc.).

The alkyl moiety of the aralkyl group represented by R¹³ may be either linear or branched. The number of carbon atoms of the aralkyl group is usually from 7 to 20, and preferably from 7 to 10. The aralkyl group is typically a phenylalkyl group such as a benzyl group, a phenylpropyl group (1-methyl-3-phenylpropyl group, etc.), or a phenylbutyl group (3-amino-1-phenylbutyl group, etc.).

The acyl group represented by R¹³ may have no substituent, or may have a substituent such as a saturated aliphatic hydrocarbon group or alkoxyl group bonded thereto. The number of carbon atoms of the acyl group is usually from 2 to 10, and preferably from 6 to 10. Examples of the acyl group include an acetyl group, a benzoyl group, and a methoxybenzoyl group (p-methoxybenzoyl group, etc.).

From the viewpoint of increase of color density, oil solubility, and light resistance of the azo compound (I), R⁵ to R¹² may be further limited. One of R⁵ to R¹² is an N-substituted sulfamoyl group. Although the azo compound (I) exhibits high oil solubility, it is recommended to employ, in addition to the N-substituted sulfamoyl group, a trifluoromethyl group as one or more of R⁵ to R¹² so as to further increase oil solubility.

When two or more kinds of azo compounds (I) are used in combination, oil solubility is higher than that in the case of using one kind alone. Therefore, the use of a combination of two or more kinds of azo compounds (I) is also a preferred aspect from the viewpoint of oil solubility. Examples of a combination which enables improvement of oil solubility include a combination of an azo compound having two N-substituted sulfamoyl groups (disulfoneamide) and an azo compound having one N-substituted sulfamoyl group and one sulfo group (monosulfoneamide). Of these combinations, preferred is a combination of disulfoneamide wherein one of R⁵ to R⁸ and one of R⁹ to R¹² represent an N-substituted sulfamoyl group and the remainder is a hydrogen atom, and monosulfoneamide wherein one of R⁵ to R⁸ is an N-substituted sulfamoyl group, one of R⁹ to R¹² is a sulfo group, and the remainder is a hydrogen atom.

From the viewpoint of increase of oil solubility, it is recommended that comparatively bulky groups are selected as one or more (for example, one or more (particularly one) from R⁵ to R⁸ and one or more (particularly one) from R⁹ to R²) among R⁵ to R¹², and one or more (for example, one or more (particularly one) from R⁵ to R⁸ and one or more (particularly one) from R⁹ to R¹²) among R⁵ to R¹² are substituted on the meta- or ortho-position of the azo group. Selection of a bulk group and substitution on the meta-position of the azo group enable reduction of stacking at the biphenyl site and improvement of oil solubility. In contrast, selection of a bulk group and substitution on the ortho-position of the azo group enable protection of the azo group and improvement of light resistance. Examples of bulky R⁵ to R¹² include, in addition to the N-substituted sulfamoyl group, a branched saturated aliphatic hydrocarbon group (particularly a tertiary saturated aliphatic hydrocarbon group such as a tert-butyl group, etc.) and a saturated aliphatic hydrocarbon group containing two or more (particularly 3 or more) halogen atoms bonded thereto (for example, a trifluoromethyl group, etc.).

From the viewpoint of more increase of color density and oil solubility, R¹³ of the N-substituted sulfamoyl group may be further limited. Examples of R¹³ include branched saturated aliphatic hydrocarbon groups such as a methylbutyl group (1,1,3,3-tetramethylbutyl group, etc.), a methylhexyl group (1,5-dimethylhexyl group, etc.), an ethylhexyl group (2-ethylhexyl group, etc.), a methylcyclohexyl group (2-methylcyclohexyl group, etc.), a phenylbutyl group (3-amino-1-phenylbutyl group, etc.), and an aralkyl group.

The azo compound (I) is preferably an azo compound wherein two or more (for example, one or more (particularly one) from R⁵ to R⁸ and one or more (particularly one) from R⁹ to R¹²) among R⁵ to R¹² represent an N-substituted sulfamoyl group. More preferred azo compound (I) is an azo compound wherein at least one of R⁵ to R⁸ and at least one of R⁹ to R¹² represent a —SO₂NHR¹³ group and the remainder of R⁵ to R¹² represents a hydrogen atom.

Preferred examples of the formula (I) include formulas (I-1) to (I-7).

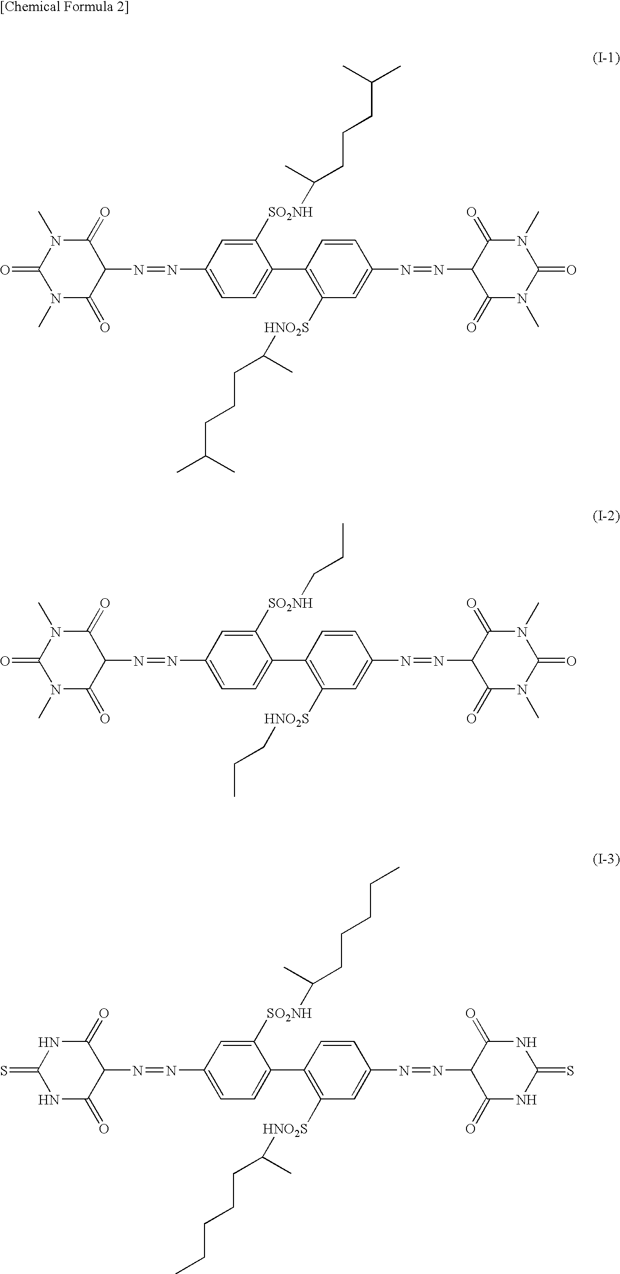

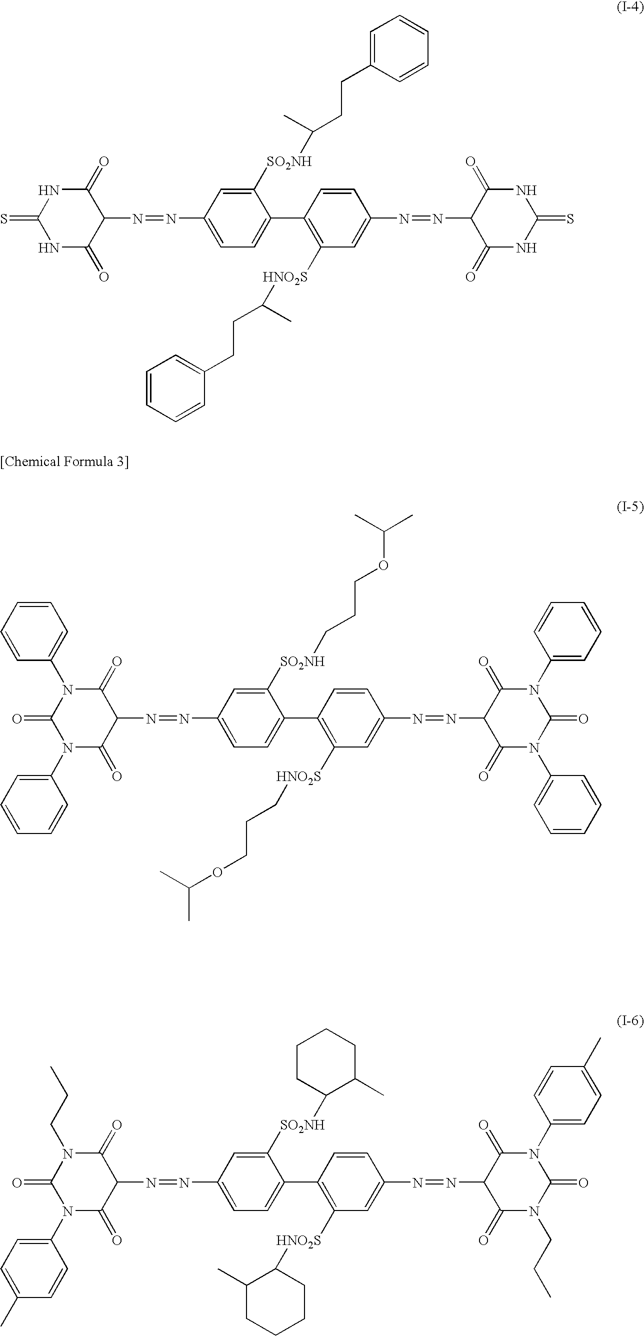

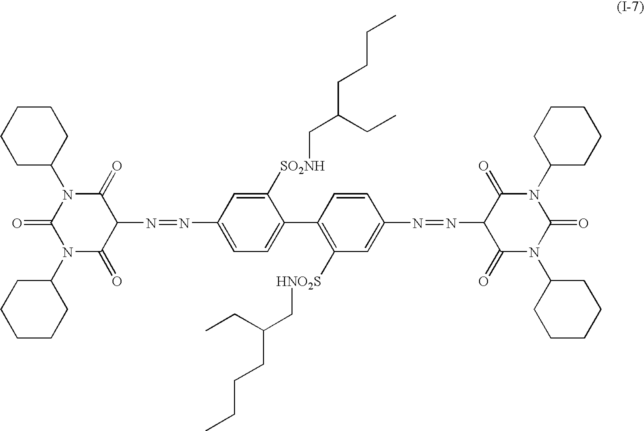

The colored photosensitive composition of the present invention is not limited to a compound represented by the formula (I) and may also include a salt thereof. Examples of the salt include sulfonates when R⁵ to R¹² represent a sulfo group, and carboxylates when R⁵ to R¹² represent a carboxyl group. The cation which forms these salts is not specifically limited, and is preferably an alkali metal salt such as a lithium salt, a sodium salt, or a potassium salt; an ammonium salt; or an organic amine salt such as an ethanolamine salt or an alkylamine salt, considering solubility in a solvent. The organic amine salt is a non-metal salt, and is therefore useful from the viewpoint of insulating properties.

The azo compound (I) may be used alone, or two or more kinds of them may be used in combination. The amount of the azo compound (I) is usually from about 10 to 70 parts by mass (preferably from 15 to 50 parts by mass, and more preferably from 20 to 40 parts by mass) based on 100 parts by mass of the total (for example, when using a xanthene pigment and a pyrazoloneazo-based pigment described hereinafter, 100 parts by mass of the total of these pigments and the azo compound (I)) of the coloring agents.

As well known in the field of dyes, the azo compound (I) can be produced by coupling a diazonium salt with barbituric acid or thiobarbituric acid (hereinafter abbreviated to “(thio(barbituric acid)”. For example, a diazonium salt represented by the formula (b) is obtained by diazotizing a benzidine compound (diazo component) represented by the formula (a) with nitrous acid, a nitrate or a nitrate ester, and the resulting diazonium salt can be used for a coupling reaction (in the formulas (a) and (b), R⁵ to R¹² are as defined above, and at least one of R⁵ to R¹² is a sulfo group or an N-substituted sulfamoyl group).

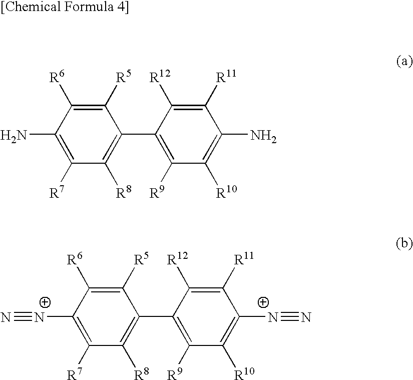

The azo compound (I) or azosulfonic acid (a precursor of the azo compound (I)) described hereinafter can be produced by usually reacting a diazonium salt (b) with (thio)barbituric acids (coupling component) represented by the formulas (c) and (d) in an aqueous solvent at 20 to 60° C. (in the formulas (c) and (d), Z¹ to Z⁴, R¹ to R⁴ are as defined above). (Thio)barbituric acids represented by the formulas (c) and (d) may be the same or different.

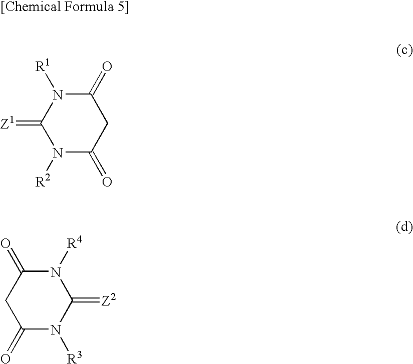

The azo compound (I) wherein at least one of R⁵ to R¹² is an N-substituted sulfamoyl group can be produced by using a compound (a) having an N-substituted sulfamoyl group, but is surely produced by performing a coupling reaction using a compound (a) having a sulfo group, followed by sulfonamidation. For example, sulfonamidation of the sulfo group can be performed by preliminarily synthesizing a compound of the formula (I) wherein at least one of R⁵ to R¹² is a sulfo group (hereinafter abbreviated to an “azosulfonic acid (i)”), converting the sulfo group (—SO₃H) into a sulfone halide (—SO₂X; X is a halogen atom) using a halogenated thionyl compound, and reacting the sulfone halide with an amine.

Preferred examples of the azosulfonic acid (i) include compounds represented by the formulas (i-1) to (i-5).

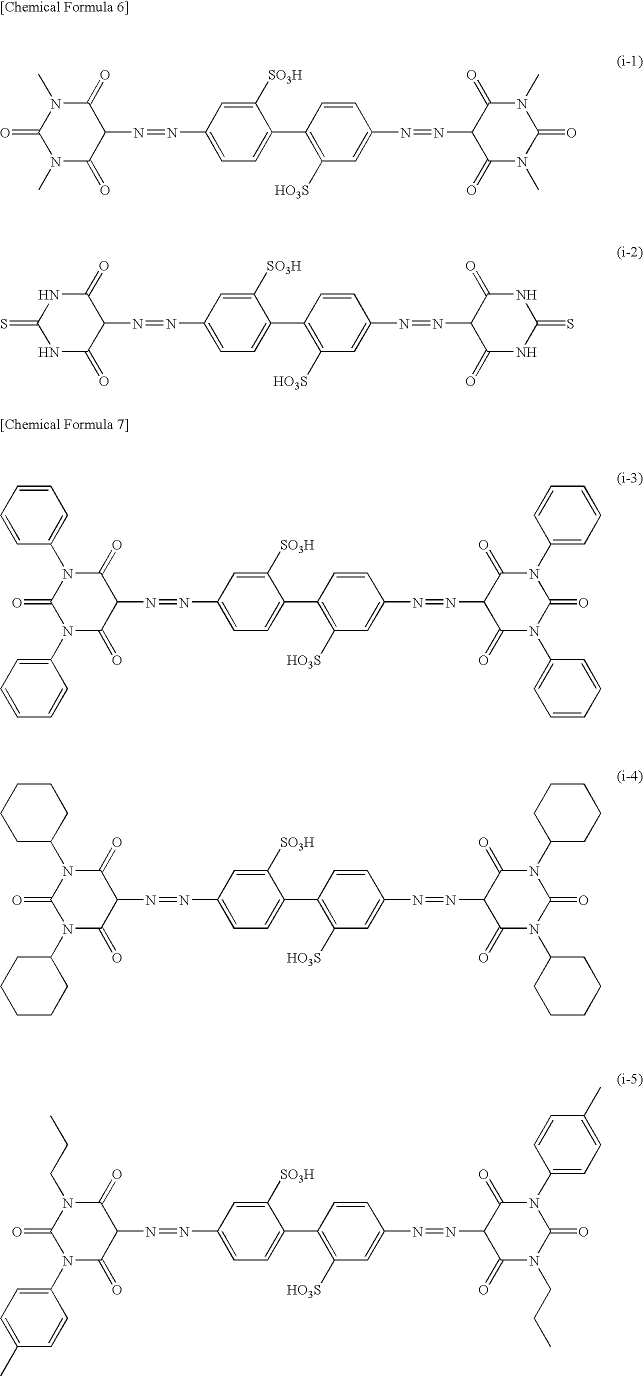

Examples of the halogenated thionyl compound are thionyl fluoride, thionyl chloride, thionyl bromide, and thionyl iodide, preferably thionyl chloride and thionyl bromide, and particularly preferably thionyl chloride. The amount of the halogenated thionyl is, for example, from about 1 to 10 mol based on 1 mol of the azosulfonic acid (i). When water is introduced in the reaction system, it is preferred to excessively use a halogenated thionyl compound.

Conversion into the sulfone halide is usually performed in a solvent. It is possible to use, as the solvent, ethers (particularly cyclic ethers) such as 1,4-dioxane; and halogenated hydrocarbons such as chloroform, methylene chloride, carbon tetrachloride, 1,2-dichloroethane, dichloroethylene, trichloroethylene, perchloroethylene, dichloropropane, amyl chloride, and 1,2-dibromoethane. The amount of the solvent is, for example, about 3 parts by mass or more (preferably 5 parts by mass or more) and about 10 parts by mass or less (preferably 8 parts by mass or less) based on 1 part by mass of the azosulfonic acid (i).

It is recommended to use N,N-dialkylformamide (for example, N,N-dimethylformamide, N,N-diethylformamide, etc.) in combination in the conversion into the sulfone halide. When N,N-dialkylformamide is used, the amount is, for example, from about 0.05 to 1 mol based on 1 mol of the halogenated thionyl. For example, when the halogenated thionyl is added after preliminarily mixing azosulfonic acid (i) with N,N-dialkylformamide in a solvent, heat generation can be suppressed.

The reaction temperature is, for example, 0° C. or higher (preferably 30° C. or higher) and 70° C. or lower (preferably 60° C. or lower). The reaction time is, for example, about 0.5 hour or more (preferably 3 hours or more) and about 8 hours or less (preferably 5 hours or less).

The sulfone halide compound thus prepared may be reacted with an amine after isolation, or may be reacted with an amine in the form of the reaction mixture without being isolated. When isolated, for example, the precipitated crystal may be collected by filtration after mixing the reaction mixture with water. The resulting crystal of the sulfone halide compound may be optionally washed with water and dried before the reaction with the amine.

The amine includes, for example, a primary amine and the primary amine is represented by the formula H₂N—R¹³ (R¹³ is as defined above). Specific examples of H₂N—R¹³ include n-propylamine, n-butylamine, n-hexylamine, dimethylhexylamine (1,5-dimethylhexylamine, etc.), tetramethylbutylamine (1,1,3,3-tetramethylbutylamine, etc.), ethylhexylamine (2-ethylhexylamine, etc.), aminophenylbutane (3-amino-1-phenylbutane, etc.), and isopropoxypropylamine. The amount of the amine is usually about 3 mol or more and about 13 mol or less (preferably 10 mol or less) based on 1 mol of the sulfone halide compound. As used herein, the amine may be referred to as a reactive amine so as to distinguish from a basic catalyst described hereinafter.

Although there is no specific limitation on the order of addition of the sulfone halide compound and amine, the amine is often added (added dropwise) to the sulfone halide compound. The reaction between the sulfone halide compound and amine is usually performed in a solvent. It is possible to use, as the solvent, the same solvent as that used when the sulfone halide compound is prepared.

The reaction between the sulfone halide and reactive amine is preferably performed in the presence of a basic catalyst. Examples of the basic catalyst include a tertiary amine (particularly aliphatic tertiary amine such as triethylamine, triethanolamine, etc.) and a pyridine base such as pyridine and methylpyridine. Of these, preferred amine is a tertiary amine, and particularly an aliphatic tertiary amine such as triethylamine. The amount of the basic catalyst is usually about 1.1 mol or more and about 3 mol or less (preferably 2 mol or less) based on the reactive amine (the amine to be reacted with the sulfone halide).

When the reactive amine and the basic catalyst are added to the sulfone halide compound, there is no specific limitation on timing of the addition of the basic catalyst, and may be added before and after the addition of the reactive amine and may be added at the same timing as that of the addition of the reactive amine. The basic catalyst may be added after preliminarily mixing with the reactive amine, or the basic catalyst and reactive amine may be separately added.

The temperature of the reaction between the sulfone halide and reactive amine is, for example, 0° C. or higher and 50° C. or lower (preferably 30° C. or lower). The reaction time is usually from about 1 to 5 hours.

There is no specific limitation on the method of obtaining an azo compound (I) from the reaction mixture, and various known methods can be employed. For example, the precipitated crystal may be collected by filtration after mixing the reaction mixture with an acid (acetic acid) and water. The acid and water are often used after preliminarily preparing an aqueous solution of the acid, and the reaction mixture is often added to the aqueous solution of the acid. The temperature at which the reaction mixture is added is usually 10° C. or higher (preferably 20° C. or higher) and 50° C. or lower (preferably 30° C. or lower). After the addition, stirring is usually performed at the same temperature for about 0.5 to 2 hours. The crystal obtained by filtration is usually washed with water and then dried. If necessary, the crystal may be further purified by a known method such as recrystallization.

Next, the red coloring agent to be used in the colored photosensitive composition of the present invention will be described. The red coloring agent includes a pigment having an absorption maximum at a wavelength of 500 to 600 nm, for example, a xanthene-based pigment. The xanthene-based pigment is preferably a pigment represented by the formula (II) (hereinafter may be abbreviated to a “xanthene-based pigment (II)”).

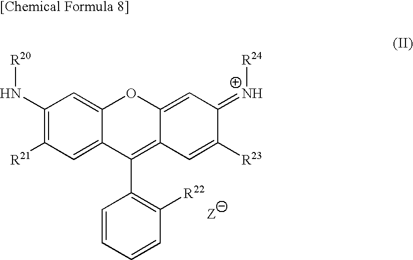

In the formula (II), Z⁻ represents BF⁴⁻, PF⁶⁻, X⁻, or XO⁴⁻ (in which X is a halogen atom).

R²¹ and R²³ each independently represents a hydrogen atom or a C₁₋₈ saturated aliphatic hydrocarbon group.

R²² represents a sulfo group, a sulfonate ester group, a carboxyl group, an alkoxycarbonyl group (carboxylate ester group), or a sulfamoyl group represented by the formula (IIa).

R²⁵HN—SO₂— (IIa)

In the formula (IIa), R²⁵ represents a hydrogen atom, a C₂₋₂₀ saturated aliphatic hydrocarbon group, a C₂₋₁₂ saturated aliphatic hydrocarbon group substituted with a cyclohexyl group, a cyclohexyl group substituted with a C₁₋₄ saturated aliphatic hydrocarbon group, a C₂₋₁₂ saturated aliphatic hydrocarbon group substituted with a C₂₋₁₂ alkoxyl group, a phenyl group which may be substituted with a C₁₋₂₀ saturated aliphatic hydrocarbon group, a C₁₋₂₀ saturated aliphatic hydrocarbon group which may be substituted with a phenyl group, an alkylcarbonyloxyalkyl group represented by the formula (IIb), or an alkoxycarbonylalkyl group represented by the formula (IIc).

R²⁶—CO—O—R²⁷— (IIb)

R²⁸—O—CO—R²⁹— (IIc)

In the formula (IIb) and (IIc), R²⁶ and R²⁸ each independently represents a C₂₋₁₂ saturated aliphatic hydrocarbon group, and R²⁷ and R²⁹ each independently represents a C₂₋₁₂alkylene group.

R²⁰ and R²⁴ each independently represents a hydrogen atom, a C₁₋₈ saturated aliphatic hydrocarbon group, or a substituted phenyl group represented by the formula (IId).

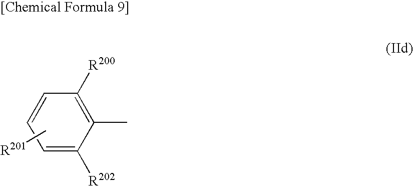

In the formula (IId), R²⁰⁰ and R²⁰² each independently represents a hydrogen atom or a C₁₋₃ saturated aliphatic hydrocarbon group, and R²⁰¹ represents a sulfo group, a sulfonate ester group, a carboxyl group, an alkoxycarbonyl group, or a sulfamoyl group represented by the formula (IIa).

The xanthene-based pigment is not limited to the compound represented by the formula (II) and may be a salt thereof. Examples of the salt include alkali metal salts such as a lithium salt, a sodium salt, and a potassium salt; and amine salts such as a triethylamine salt and a 1-amino-3-phenylbutane salt. In the compound represented by the formula (II), when the substituent R²² is a sulfo group or a carboxyl group, the sulfo group or carboxyl group forms a salt thereof.

As the xanthene-based pigment (II) wherein R²⁰ and R²⁴ represent a substituted phenyl group (hereinafter abbreviated to an “(aryl)aminoxanthene-based pigment (II)”), those represented by the following formulas (II-1) and (II-2) are preferred.

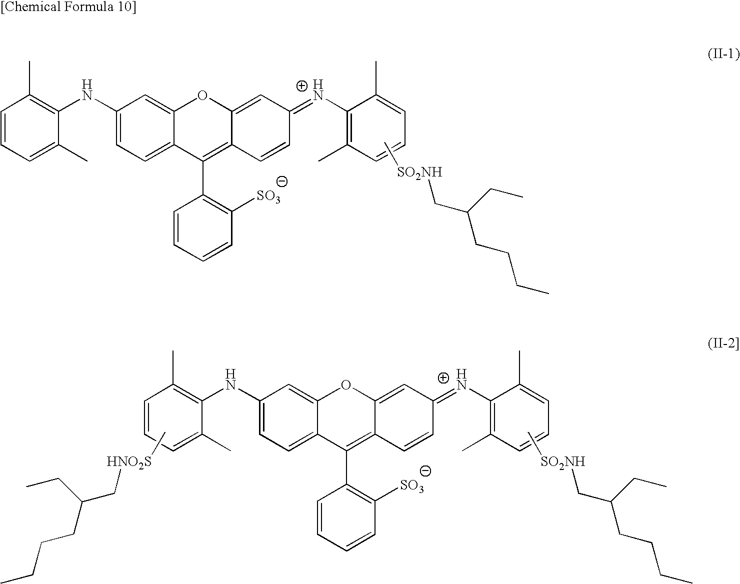

Examples of commercially available (aryl)aminoxanthene-based pigment (II) include C.I. Acid Red 289.

A xanthene-based pigment (II) wherein R²⁰, R²¹, R²³, and R²⁴ each independently represents a C₁₋₅ (particularly C₁₋₃) saturated aliphatic hydrocarbon group (hereinafter abbreviated to an “(alkyl)aminoxanthene-based pigment (II)”) is more preferred as compared with the (aryl)aminoxanthene-based pigment (II). The (alkyl)aminoxanthene-based pigment (II) can further increase color density (absorbance) and also can further improve spectral characteristics of a color filter array as compared with the (aryl)aminoxanthene-based pigment (II) without causing any change of color (maximum absorption wavelength) of the color filter array (red filter layer). Of the (alkyl)aminoxanthene-based pigment (II), those in which R²² is a sulfo group (including the from of sulfonate), or a (C₁₋₅ alkoxy) carbonyl group (particularly (C₁₋₃ alkoxy)carbonyl group) are preferred. C.I. Basic Acid 289 is included in preferred (alkyl)aminoxanthene-based pigment (II).

The xanthene-based pigment (II) may be used alone, or two or more kinds of them may be used in combination. When the xanthene-based pigment (II) is used, the amount is preferably from about 0.1 to 70 parts by mass (more preferably from 10 to 60 parts by mass, and still more preferably from 20 to 40 parts by mass) based on 100 parts by mass of the total of the coloring agents.

The other pigment may be further used in combination as long as it does not exert an adverse influence on the effects of the present invention. Spectral characteristics of the color filter array (red filter layer) can be more improved by using, as the yellow coloring agent, a pigment having an absorption maximum at a wavelength of 400 to 550 nm in combination. Examples of the pigment include a pyrazoloneazo-based pigment. As the pyrazoloneazo-based pigment, a known pyrazoloneazo-based pigment can be used. More specifically, a compound represented by the formula (III), or a salt (an alkali metal salt, an amine salt, etc.) thereof, or a complex (a chromium complex, etc.) thereof (hereinafter abbreviated to a “pyrazoloneazo-based pigment (III)”) can be used.

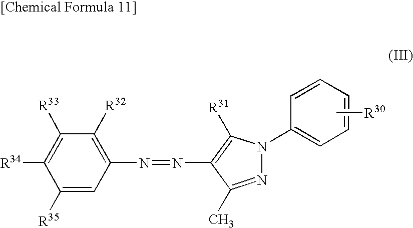

In the formula (III), R³¹ and R³² each independently represents a hydroxyl group or a carboxyl group. R³⁰, R³³, R³⁴, and R³⁵ each independently represents a hydrogen atom, a halogen atom, a C₁₋₄ saturated aliphatic hydrocarbon group, a C₁₋₄ alkoxyl group, a sulfo group, or a nitro group.

Specific examples of the pyrazoloneazo-based pigment (III) include C.I. Acid Yellow 17, C.I. Solvent Orange 56, and C.I. Solvent Yellow 82.

The pyrazoloneazo-based pigment (III) may be used alone, or two or more kinds of them may be used in combination. When the pyrazoloneazo-based pigment (III) is used, the amount is usually from about 0.1 to 70 parts by mass (preferably from 20 to 40 parts by mass) based on 100 parts by mass of the total of the coloring agents.

The colored photosensitive composition of the present invention usually contains, in addition to the coloring agents, a photosensitive compound and an alkali-soluble resin in both case of a positive composition and a negative composition.

The photosensitive compound is appropriately selected according to the positive composition or the negative composition.

The photosensitive compound for a positive composition is generally referred to as a photosensitizer and known various photosensitizers can be used. Specific examples of the photosensitizer include an ester of a phenol compound and an o-naphthoquinonediazidesulfonic acid compound (o-naphthoquinonediazide-5-sulfonic acid, o-naphthoquinonediazide-4-sulfonic acid, etc.).

Examples of the phenol compound include a di-, a tri-, a tetra- or a pentahydroxybenzophenone (2,3,4,4′-tetrahydroxybenzophenone, etc.), and compounds represented by the formulas (11) to (21).

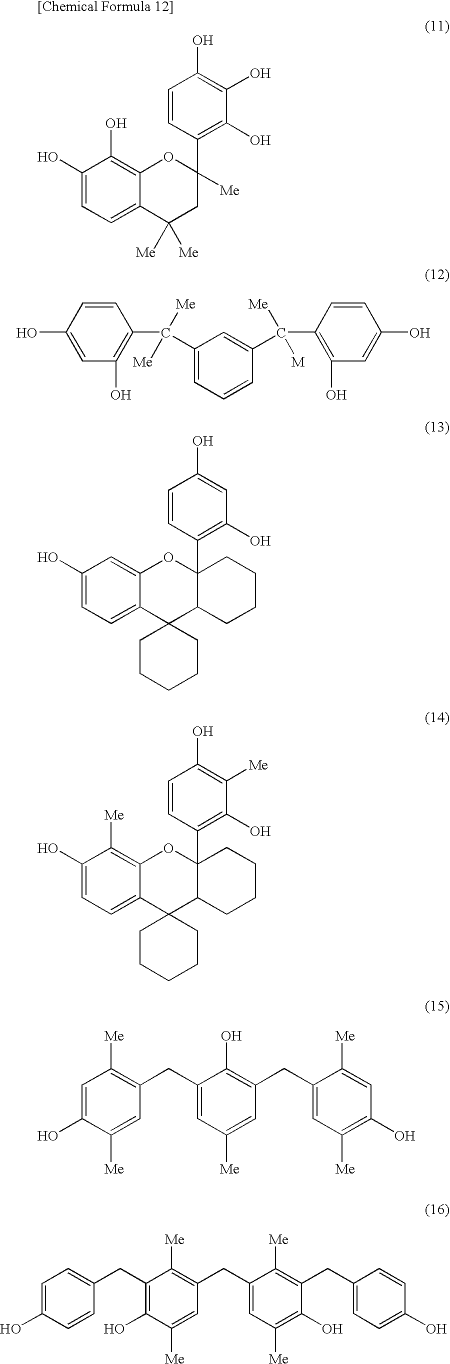

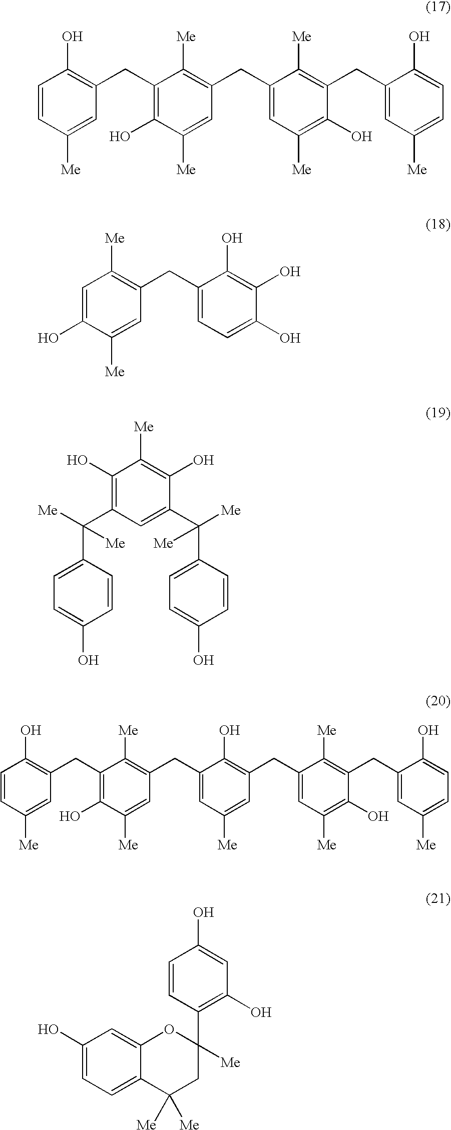

A photo acid generator can be used as the photosensitive compound for a negative composition. The kind of the photo acid generator is not specifically limited and known various photo acid generators (for example, an iodonium salt compound, a sulfonium salt compound, an organic halogen compound (haloalkyl-s-triazine compound, etc.), a sulfonate ester compound, a disulfone compound, a diazomethanesulfonyl compound, an N-sulfonyl oxyimide compound, an oxime-based compound, etc.) can be used. The photo acid generator is preferably an oxime-based compound.

Examples of the oxime-based compound include cyanides such as α-(4-toluenesulfonyloxyimino)benzyl cyanide, α-(4-toluenesulfonyloxyimino)-4-methoxybenzyl cyanide, α-(camphorsulfonyloxyimino)-4-methoxybenzyl cyanide, α-trifluoromethanesulfonyloxyimino-4-methoxybenzyl cyanide, α-(1-hexanesulfonyloxyimino)-4-methoxybenzyl cyanide, α-naphthalenesulfonyloxyimino-4-methoxybenzyl cyanide, α-(4-toluenesulfonyloxyimino)-4-N-diethylanilyl cyanide, α-(4-toluenesulfonyloxyimino)-3,4-dimethoxybenzyl cyanide, and α-(4-toluenesulfonyloxyimino)-4-thienyl cyanide; and acetonitriles such as α-[(4-toluenesulfonyloxyimino)-4-methoxyphenyl]acetonitrile, (5-tosyloxyimino-5H-thiophen-2-ylidene)-(2-methylphenyl)acetonitrile, (5-camphorsulfonyloxyimino-5H-thiophen-2-ylidene)-(2-methylphenyl)acetonitrile, (5-n-propyloxyimino-5H-thiophen-2-ylidene)-(2-methylphenyl)acetonitrile, and (5-n-octyloxyimino-5-camphorsulfonyloxyimino-5H-thiophen-2-ylidene)-(2-methylphenyl)acetonitrile.

As the alkali-soluble resin, known various alkali-soluble resins used in a photoresist material can be used and, for example, a novolak resin and a polyvinyl resin are used. Specific examples of the novolak resin include a p-cresol novolak resin, an m-cresol novolak resin, a novolak resin of p-cresol and m-cresol, and a novolak resin having a repeating structure represented by the formula (31).

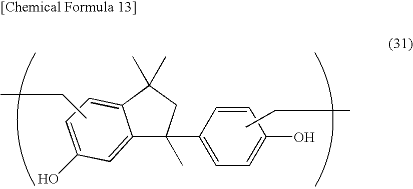

Examples of the polyvinyl resin include a polymer of vinylphenol (p-vinylphenol (also referred to as p-hydroxystyrene), etc.). This polymer may be a homopolymer, or a copolymer (for example, a copolymer of styrene and p-vinylphenol). If necessary, a hydrogen atom of a hydroxyl group of vinylphenol may be substituted (masked) with an organic group (for example, a C₁₋₆ alkyl group). When the hydroxyl group is masked with the organic group, the exposure dose upon formation of a pattern using a photolithography method can be decreased, and also it become easy to make a pattern shape to be a rectangular shape, which is preferred as a color filter.

The polystyrene equivalent weight average molecular weight of the novolak resin is, for example, from about 3,000 to 20,000, and the polystyrene equivalent weight average molecular weight of the polyvinyl resin is, for example, from about 1,000 to 20,000, and preferably from about 2,000 to 6,000.

The contents of the coloring agent, the photosensitive compound, and the alkali-soluble resin (based on 100 parts by mass of the total of the coloring agent, the photosensitive compound, and the alkali-soluble resin (solid content)) are as follows.

Coloring agent: For example, by controlling the amount of the coloring agent within a range from about 5 to 80 parts by mass, preferably from about 15 to 80 parts by mass, more preferably from about 20 to 70 parts by mass, and particularly from about 30 to 70 parts by mass, color density of the color filter can be sufficiently increased, and also thickness loss in the developing step upon formation of a pattern can be decreased.

Photosensitive Compound: For example, by controlling the amount of the photosensitive compound within a range from about 0.001 to 50 parts by mass, preferably from about 0.01 to 40 parts by mass, more preferably from about 0.1 to 30 parts by mass, and particularly from about 0.1 to 10 parts by mass, thickness loss in the developing step upon formation of a pattern can be decreased, and also the projection exposure time in formation of a pattern using a photolithography method can be shortened.

Alkali-Soluble Resin: When the amount of the alkali-soluble resin is within a range from about 1 to 75 parts by mass, preferably from about 5 to 60 parts by mass, and more preferably from about 10 to 50 parts by mass, sufficient solubility in a developing solution is achieved, and also thickness loss is less likely to occur in the developing step and exposure dose upon formation of a pattern using a photolithography method decreases preferably.

The colored photosensitive composition of the present invention conventionally contains a curing agent (a crosslinking agent) and also contains a solvent and a surfactant, if necessary. A compound having a thermocuring action can be used as the curing agent and, for example, it is possible to use a melamine compound represented by the formula (41).

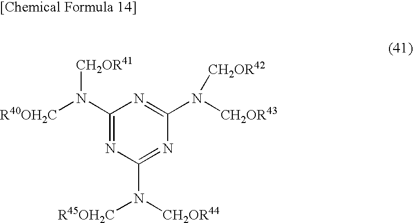

In the formula (41), R⁴⁰ to R⁴⁵ each independently represents a hydrogen atom, a linear C₁₋₁₀ (preferably C₁₋₄) saturated aliphatic hydrocarbon group, or a branched C₃₋₁₀ saturated aliphatic hydrocarbon group (preferably an isopropyl group, an isobutyl group, a sec-butyl group, a tert-butyl group, etc.), provided that at least two substituents among R⁴⁰ to R⁴⁵ are not hydrogen atoms.

The content of the curing agent is, for example, from about 10 to 40% by mass, and preferably from about 15 to 30% by mass, based on the solid content of the colored photosensitive composition. When the amount of the curing agent is within the above range, the exposure dose in the case of forming a pattern using a photolithography method can be decreased. The pattern after developing has satisfactory shape and the pattern after curing by heating has a sufficient mechanical strength. Since thickness loss of a pixel pattern is not generated during the developing step, color unevenness of the image scarcely occurs.

The solvent can be appropriately selected according to solubility of the coloring agent (pigment), the photosensitive compound, the alkali-soluble resin, and the curing agent contained in the colored photosensitive composition (particularly solubility of the coloring agent). Examples of the solvent include ethylene glycols (methyl cellosolve, ethyl cellosolve, methyl cellosolve acetate, ethyl cellosolve acetate, diethylene glycol dimethyl ether, ethylene glycol monoisopropyl ether, etc.), propylene glycols (propylene glycol monomethyl ether, propylene glycol monomethyl ether acetate, etc.), N-methylpyrrolidone, γ-butyrolactone, dimethyl sulfoxide, N,N-dimethylformamide, ketones (4-hydroxy-4-methyl-2-pentanone, cyclohexanone, etc.), and carboxylate esters (ethyl acetate, n-butyl acetate, ethyl pyruvate, ethyl lactate, n-butyl lactate, etc.). These solvents may be used alone, or two or more kinds of them may be used in combination.

The content of the solvent is, for example, from about 65 to 95% by mass, and preferably from about 70 to 90% by mass, based on the colored photosensitive composition. When the content of the solvent is within the above range, uniformity of the coating film is improved.

Examples of the surfactant include silicone-based surfactants, for example, surfactants having a siloxane bond such as Toray Silicone DC3PA, SH7PA, DC11PA, SH21PA, SH28PA, 29SHPA, SH30PA and polyether-modified silicone oil SH8400 (all of which are manufactured by Toray Silicone Co., Ltd., KP321, KP322, KP323, KP324, KP326, KP340 and KP341 (all of which are manufactured by Sin-Etsu Silicone Co., Ltd.), and TSF400, TSF401, TSF410, TSF4300, TSF4440, TSF4445, TSF-4446, TSF4452 and TSF4460 (all of which are manufactured by GE Toshiba Silicone Co., Ltd.); fluorine-based surfactants, for example, surfactants having a fluorocarbon chain such as Florard FC430 and FC431 (all of which are manufactured by Sumitomo 3M Ltd.), Megafac F142D, F171, F172, F173, F177, F183 and R30 (all of which are manufactured by Dainippon Ink and Chemicals, Incorporated), F Top F301, EF303, EF351 and EF352 (all of which are manufactured by Shinakita Kasei Co., Ltd.), Surflon S381, S382, SC101 and SC105 (all of which are manufactured by Asahi Glass Co., Ltd.), E5844 (all of which are manufactured by Daikin Fine Chemical Laboratory, Ltd.), and BM-1000 and BM-1100 (all of which are manufactured by BM Chemie Co.); and silicone-based surfactants having a fluorine atom, for example, surfactants having a siloxane bond and a fluorocarbon chain such as Megafac R08, BL20, F475, F477 and F443 (all of which are manufactured by Dainippon Ink and Chemicals, Incorporated). These surfactants may be used alone, or two or more kinds of them may be used in combination.

When the surfactant is used, the amount is, for example, from about 0.0005% to 0.6% by mass, and preferably from about 0.001% to 0.5% by mass, based on the colored photosensitive composition. When the surfactant is used in the amount within the above range, smoothness of the colored photosensitive composition during coating is further improved.

When the colored photosensitive composition of the present invention is a negative composition, it may further contain an amine-based compound. The use of the amine-based compound enables prevention of a drastic change of the exposure dose in the case of photolithography before and after long-term storage of the colored photosensitive composition. The use of the amine-based compound enables decrease of a dimensional of a resist pattern as a result of deactivation of the photo acid generator when the substrate is allowed to stand after exposure.

Examples of the amine-based compound which is useful to exert the former effect of stabilizing the exposure dose include aminoalcohols such as 3-amino-1-propanol, 1-amino-2-propanol, 2-amino-1-propanol, 2-amino-2-methyl-1-propanol, 2-amino-2-methyl-1-propanol, 2-amino-2-methyl-1,3-propanediol, and 3-methyl-2-amino-1-butanol; and compounds having a diazabicyclo structure, such as 1,4-diazabicyclo[2,2,2]octane, 1,8-diazabicyclo[5,4,0]-7-undecene, and 1,5-diazabicyclo[4,3,0]non-5-ene.

Examples of the amine-based compound which is useful to exert the latter dimension stabilizing effect include 4-nitroaniline, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, 4,4′-diamino-3,3′,5,5′-tetraethyldiphenylmethane, 8-quinolylol, benzimidazole, 2-hydroxybenzimidazole, 2-hydroxyquinazoline, 4-methoxybenzylidene-4′-n-butylaniline, salicylic acid amide, salicylanilide, 1,8-bis(N,N-dimethylamino)naphthalene, 1,2-diazine(pyridazine), piperidine, p-aminobenzoic acid, N-acetylethylenediamine, 2-methyl-6-nitroaniline, 5-amino-2-methylphenol, 4-n-butoxyaniline, 3-ethoxy-n-propylamine, 4-methylcyclohexylamine, 4-tert-butylcyclohexylamine, monopyridines (imidazole, pyridine, 4-methylpyridine, 4-methylimidazole, 2-dimethylaminopyridine, 2-methylaminopyridine, 1,6-dimethylpyridine, etc.), bipyridines (bipyridine, 2,2′-dipyridylamine, di-2-pyridylketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridylsulfide, 4,4′-dipyridyldisulfide, 1,2-bis(4-pyridyl)ethylene, 2,2′-dipicolylamine, 3,3′-dipicolylamine, etc.), and ammonium salts (tetramethylammonium hydroxide, tetraisopropylammonium hydroxide, tetrabutylammonium hydroxide, tetra-n-hexylammonium hydroxide, tetra-n-octylammonium hydroxide, phenyltrimethylammonium hydroxide, 3-(trifluoromethyl)phenyltrimethylammonium hydroxide, choline, etc.).

The content of the amine-based compound is, for example, from about 0.01 to 10% by mass, and preferably from about 0.1 to 0.8% by mass, based on the solid content of the colored photosensitive composition.

Furthermore, the colored photosensitive composition of the present invention may contain various additive components such as epoxy-based resins, oxetane compounds, ultraviolet absorbers, antioxidants, chelating agents, etc. as long as the effects of the present invention are not impaired.

The colored photosensitive composition can be prepared by mixing components in a solvent. The colored photosensitive composition thus prepared is usually filtered through a filter having a pore size of about 0.1 μm or less. Uniformity in the case of application of the colored photosensitive composition can be improved by filtration.

The colored photosensitive composition of the present invention can be formed into a color filter array in accordance with a photolithography method similar to a conventional photosensitive composition. In the photolithography method, for example, a pixel may be formed by forming a coating film composed of the colored photosensitive composition of the present invention on a substrate, exposing the coating film and developing the coating film. A color filter array can be formed by repeating formation, exposure and development of the coating film with respect to each color.

Known substrates can be used as the substrate. For example, a silicon wafer with an image sensor such as a solid image pickup device formed thereon, a transparent glass plate, and a quartz plate can be used.

There is no specific limitation on the method of forming a coating film on a substrate, and there can be appropriately use conventional coating methods such as a spin coating method, a roll coating method, a bar coating method, a die coating method, a dip coating method, a cast coating method, a roll coating method, and a slit&spin coating method. A coating film can be formed by applying the colored photosensitive composition of the present invention on a substrate, and heating (for example, heating to 70-120° C.) the colored photosensitive composition thereby removing a volatile component such as a solvent.

When the coating film is exposed, the coating film is irradiated with rays through a mask pattern corresponding to the objective pattern. As rays, for example, g-rays and i-rays can be used and steppers such as g-ray and i-ray steppers may be employed. The exposure dose of rays in the irradiation region is appropriately selected according to the kind and content of the photosensitive compound, the kind and content of the curing agent, and polystyrene equivalent weight average molecular weight, monomer ratio, and content of the alkali-soluble resin. The coating film thus formed may be heated. The curing agent is cured by heating and thus the mechanical strength of the coating film increases. The heating temperature is, for example, from about 80 to 150° C.

In the development, similar to the case of using a conventional photosensitive composition, a substrate with a coating film formed thereon may be brought into contact with a conventional developing solution. There is no specific limitation on the developing solution. For example, an aqueous alkali solution is used and may be optionally mixed with a surfactant. The objective pixel can be formed by shaking off the developing solution and washing with water thereby to remove the developing solution. Alternatively, the developing solution is shaken off, followed by rinsing with a rinsing solution and further washing with water. The residue of the colored photosensitive composition on the substrate during the development can be removed by rinsing.

After the development, the pixel may be optionally irradiated with ultraviolet rays. The remaining photosensitizer can be decomposed by irradiation with ultraviolet rays. After washing with water, the pixel may be heated. The mechanical strength of the pixel can be increased. The heating temperature is usually from about 160° C. to 220° C. When the heating temperature is within the above range, curing by the use of the curing agent satisfactorily proceeds without causing substantial decomposition of a pigment (coloring agent).

The thickness of the color filter array thus obtained is, for example, from about 0.4 to 2.0 μm. The longitudinal length and the lateral length of each pixel can be independently set within a range from about 1.0 to 20 μm.

The color filter array of the present invention can be formed on devices such as solid image pickup devices (CCD, CMOS sensor, etc.) and liquid crystal display devices, and is useful for coloration of these devices.

Typical examples in the case of forming the color filter array of the present invention on a CCD image sensor, and a camera system using the same will now be described in more detail with reference to the accompanying drawings.

CCD Image Sensor:

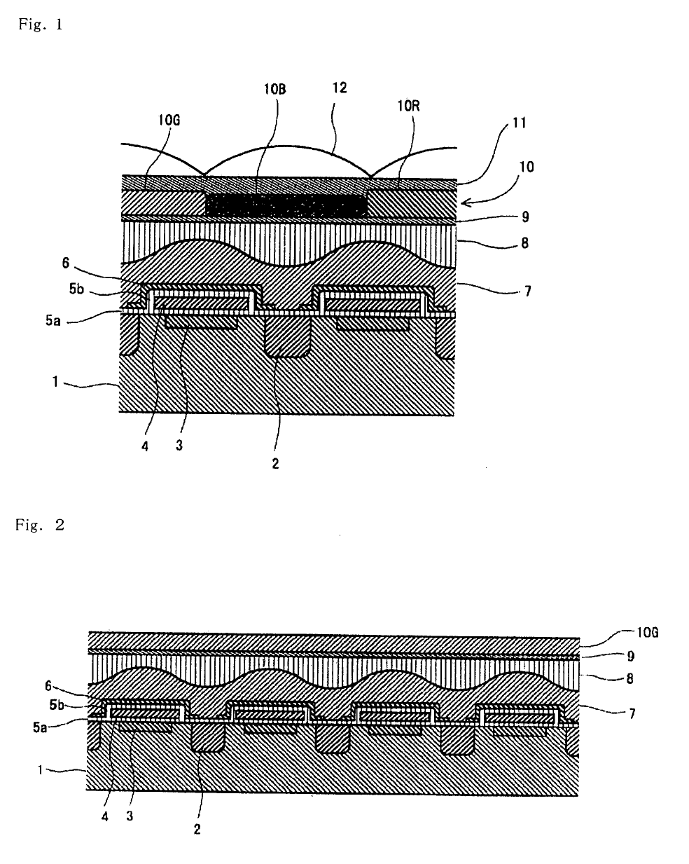

FIG. 1 is a partially enlarged schematic sectional view showing an example of a CCD image sensor on which the color filter array of the present invention is formed, and FIG. 2 to FIG. 7 are partially enlarged schematic sectional views showing procedures for formation of a color filter on the CCD image sensor shown in FIG. 1.

In the CCD image sensor of the illustrated example, a photodiode 2 is formed by ion injection of N-type impurities such as P and As on a portion of the surface of a P-type impurity region in a silicone substrate 1, followed by a heat treatment. On the surface of the silicone substrate 1 (the region which is different from a photodiode formation site), a vertical charge transfer section 3 composed of an impurity diffusion layer having a higher concentration of N-type impurities than that in the photodiode 2 is formed. The vertical charge transfer section 3 can be formed by ion injection of N-type impurities such as P and As and the subsequent heat treatment, and fulfils the role as CCD of transferring charges generated, when the photodiode 2 receives incident light, in the longitudinal direction.

In the CCD image sensor of the illustrated example, the impurity region of the silicone substrate 1 is allowed to serve as a P-type impurity layer, while the photodiode 2 and the vertical charge transfer section 3 are allowed to serve as an N-type impurity layer. Alternatively, impurity region of the silicone substrate 1 is allowed to serve as an N-type impurity layer, while the photodiode 2 and the vertical charge transfer section 3 are allowed to serve as a P-type impurity layer.

On the silicone substrate 1, the photodiode 2 and the vertical charge transfer section 3, for example, an insulating film 5a composed of SiO₂ is formed. A vertical charge transfer electrode 4 composed of poly Si is formed through the insulating film 5a is formed above the upper portion of the vertical charge transfer section 3. The vertical charge transfer electrode 4 fulfill the role as a transfer gate of transferring charges generated on the photodiode 2 to the vertical charge transfer section 3, and also fulfils the role as a transfer electrode of transferring charges transferred to the vertical charge transfer section 3 in the longitudinal direction of the CCD image sensor.

A light shielding film 6 is formed above and at the side of the vertical charge transfer electrode 4 through an insulating film 5b composed of SiO₂. The light shielding film 6 is composed of metal such as tungsten, tungsten silicide, Al, or Al-silicide, and fulfils the role of preventing incidence of incident light into the vertical charge transfer electrode 4 or the vertical charge transfer section 3. An overhanging portion is provided on the light shielding film 6 above the photodiode 2 among the side of the light shielding film 6, and thus preventing incidence of incident light into the vertical charge transfer section 3.

A BPSG film 7 is formed above the light shielding film 6 in a convex form downwardly toward the photodiode 2, and also a P—SiN film 8 is laminated thereon. The BPSG film 7 and the P—SiN film 8 are laminated so that an interface between these films curves downwardly above the photodiode 2, and fulfils the role of an intra-layer lens for efficiently leading incident light to the photodiode 2. On the surface of the P—SiN film 8, a flattened film 9 is formed for the purpose of flattening this surface or uneven portions other than the pixel region.

On a flattened film layer 9, a color filter array 10 is formed. The color filter array 10 may be formed in accordance with the above photolithography method. Description is made by way of the CCD image sensor as an example as shown in FIG. 2 to FIG. 7. While description is made by way of a negative colored photosensitive composition as an example in this illustrated example, a positive colored photosensitive composition may also be used as the example.

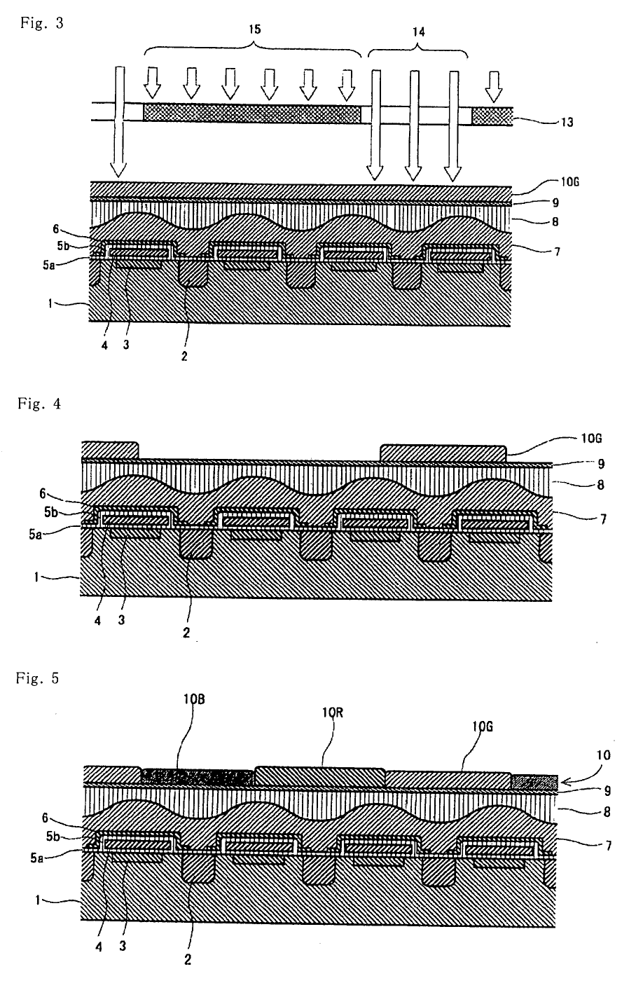

To form the color filter array, first, a photosensitive resin composition colored with a first color (in the illustrated example, a green photosensitive resin composition 10G) (see FIG. 2) is applied on a flattened film 9 and then projection exposure of a pattern through a photomask 13 is conducted (see FIG. 3). This exposure enables the green photosensitive resin composition in the exposed area 14 to be insoluble in a developing solution. The green photosensitive resin composition in the unexposed area 15 is soluble in the developing solution and then dissolved in the developing solution to form a pattern. Thereafter, the insolubilized green photosensitive resin composition in the remaining exposed area 14 is thermocured to form a desired green pixel pattern 10G (FIG. 4).

Next, the same step is repeated with respect to pixel patterns of other colors (in the illustrated example, a red pixel pattern 10R and a blue pixel pattern 10B) to form pixel patterns of three colors on the same plane of the substrate on which the image sensor is formed (FIG. 5).

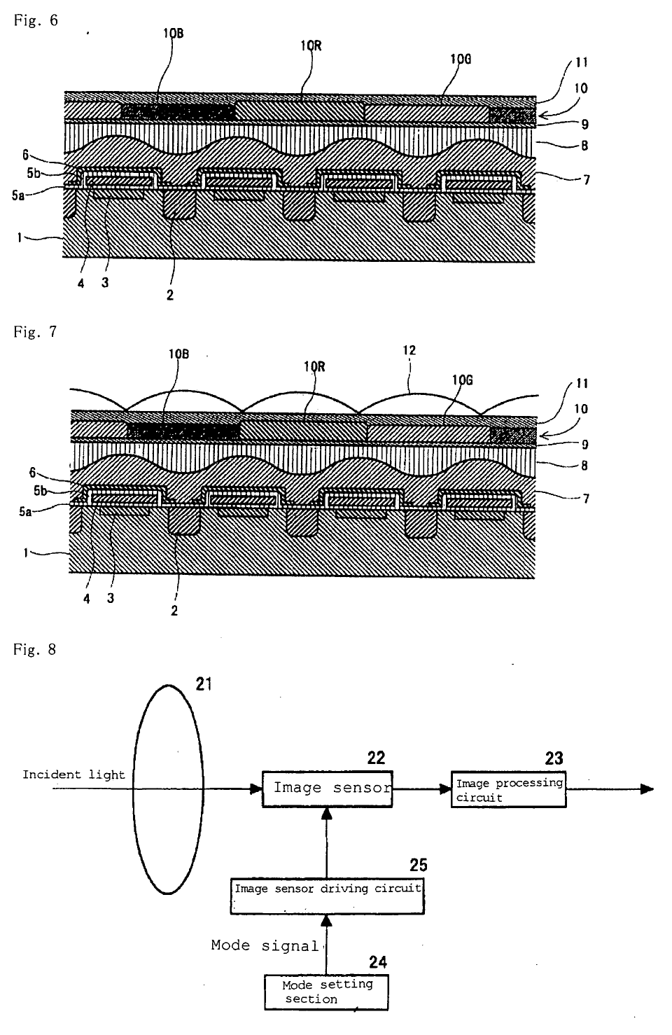

On the surface of the color filter array 10 thus formed, a flattened film 11 is formed (FIG. 6) for the purpose of flattening the unevenness. Furthermore, a microlens 12 for efficiently collecting light incident to the photodiode 2 is formed on the top surface of the flattened film 11 (FIG. 1, FIG. 7), thereby forming a CCD image sensor and a camera system using the same.

FIG. 8 is a block diagram showing an example of a camera system into which a solid image pickup device (image sensor) is incorporated. In this camera system, incident light is incident to an image sensor 22 via a lens 21. On the light incident side of the image sensor 22, the above microlens 12 (on-chip lens) and color filter array 10 are formed, and a signal corresponding to each color of incident light is output. The signal from the image sensor 22 is signal-processed by the signal processing circuit 23 and then outputted to the camera.

In the camera system of the illustrated example, the image sensor 22 is driven by a device driving circuit 25. The operation of the device driving circuit 25 can be controlled by sending a mode signal such as a static image mode or a moving image mode from a mode setting section 24. The present invention can be applied to not only a CCD image sensor, but also an amplified solid image pickup device such as a CMOS image sensor, and a camera system and a liquid crystal display device using the same.

### EXAMPLES

The present invention is further illustrated by the following Examples. It is to be understood that the present invention is not limited to the Examples, and various design variations made in accordance with the purports described hereinbefore and hereinafter are also included in the technical scope of the present invention. Percentages and parts in the amounts of the following components are by weight unless otherwise specified.

### Synthesis Example 1

To 30 parts of 2,2′-benzidinedisulfonic acid (containing 30% water), 300 parts of water was added and the pH was adjusted to 7-8 with an aqueous 30% sodium hydroxide solution. The following operation was performed under ice cooling. Sodium nitrite (12.6 parts) was added, followed by stirring for 30 minutes. 35% hydrochloric acid (38.1 parts) was added by small portions to give a brown solution, followed by stirring for 2 hours. An aqueous solution prepared by dissolving 5.3 parts of amidesulfuric acid in 57.4 parts of water was added to the reaction solution, followed by stirring to obtain a suspension containing a diazonium salt.

To 18.6 parts of N,N-dimethylbarbituric acid, 372 parts of water was added and the pH was adjusted to 8-9 with an aqueous 30% sodium hydroxide solution under ice cooling.

The following operation was performed under ice cooling. An aqueous alkali solution of the barbituric acid was converted into a colorless solution by stirring, and then a suspension containing a diazonium salt was added dropwise using a pump while adjusting the pH to 8-9 with an aqueous 30% sodium hydroxide solution. After completion of the dropwise addition, the solution was further stirred for 3 hours to obtain a yellow suspension. The yellow solid obtained by filtration was dried under reduced pressure at 60° C. to obtain 14.6 parts of azosulfonic acid represented by the formula (i-1).

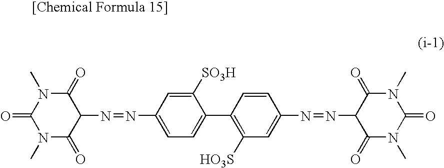

In a flask equipped with a condenser tube and a stirrer, 10 parts of azosulfonic acid (i-1), 100 parts of chloroform and 4.2 parts of N,N-dimethylformamide were placed and then 7 parts of thionyl chloride was added dropwise under stirring while maintaining at 20° C. or lower. After completion of the dropwise addition and heating to 50° C., the reaction was performed while maintaining at the same temperature for 5 hours. After cooling to 20° C., a mixed solution of 5 parts of 1,5-dimethylhexylamine and 15 parts of triethylamine was added dropwise while maintaining the reaction solution at 20° C. or lower under stirring. Then, the reaction was performed while stirring at the same temperature for 5 hours. The solvent in the resulting reaction mixture was distilled off using a rotary evaporator and a small amount of methanol was added, followed by vigorous stirring. The mixture thus obtained was added in a mixed solution of 58 parts of acetic acid and 600 parts of ion-exchange water thereby precipitating a crystal. The precipitated crystal was separated by filtration, washed well with ion-exchange water and then dried at 60° C. under reduced pressure to obtain 10.9 parts (yield: 82%) of an azo compound represented by the formula (I-1).

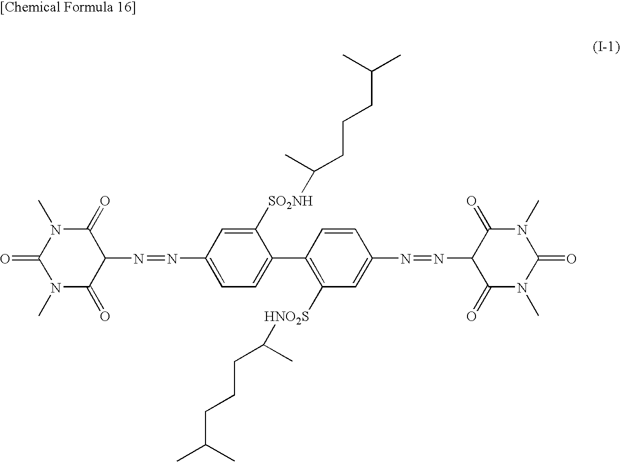

### Synthesis Example 2

Poly(p-hydroxystyrene) [trade name: “MARUKA LYNCUR M” (manufactured by Maruzen Petrochemical Co., Ltd.), weight average molecular weight (catalog value): 4,100, dispersion degree (catalog value): 1.98] (36.0 parts) and acetone (144 parts) were placed in a reaction vessel and then dissolved while stirring. To the solution, 20.7 parts of anhydrous potassium carbonate and 9.35 parts of ethyl iodide were added, and then reflux was initiated by heating. After reflux was continued for 15 hours, 72 parts of methyl isobutyl ketone was added and the organic layer was washed with 92.8 parts of an aqueous 2% oxalic acid solution. Then, 96 parts of ethyl isobutyl ketone was added and the organic layer was washed with 64.7 parts of ion-exchange water. The organic layer before washing was concentrated to 78.3 parts and, after 187.9 parts of propylene glycol monomethyl ether acetate was added, the organic layer was further concentrated to 117.4 parts. The resulting concentrated solution had a solid content of 30.6%. ¹H-NMR measurement revealed that 19.5% of hydroxyl groups of poly(p-hydroxystyrene) are ethyletherified in the resin after the reaction. This resin is referred to as a resin A.

### Example 1

The azo compound (1-1) (20 parts) obtained in Synthesis Example 1, α-[(4-toluenesulfonyloxyimino)-4-methoxyphenyl]acetonitrile (4 parts) as a photosensitive compound, the resin A obtained in Synthesis Example 2 (59 parts in terms of a solid content) as an alkali-soluble resin, hexamethoxymethylolmelamine (16.4 parts) as a curing agent, 4-hydroxy-4-methyl-2-pentanone (392 parts) as a solvent, propylene glycol monomethyl ether (98 parts) as a solvent, and 2-amino-2-methyl-1-propanol (0.15 part) as an amine-based compound were mixed and then filtered with a membrane filter having a pore diameter of 0.2 μm to obtain a red-colored photosensitive composition.

The colored photosensitive composition was applied on a quartz wafer using a spin coating method so as to control the thickness of the resulting film to 0.70 μm, and then heated at 100° C. for one minute thereby to remove a volatile component, and thus a coating film was formed. The coating film was irradiated with ultraviolet light and then heated at 200° C. for 3 minutes to obtain a filter. Patterning through exposure and development was not performed since the main object is to evaluate spectral characteristics in Example 1. However, patterning through exposure and development can be performed in the same manner as in the prior art.

### Comparative Example 1

In the same manner as in Example 1, except that C.I. Solvent Yellow 162 was used in place of the azo compound (1-1), a red colored photosensitive composition and a red filter were obtained.

Evaluation of Light Resistance

Each of the filters obtained in Example 1 and Comparative Example 1 was irradiated with light and an average light transmittance at a wavelength of 400 to 700 nm was measured before and after irradiation with light. Light resistance of the filter was evaluated by a variation (difference) in the average light transmittance before and after irradiation with light. The smaller the change, the better light resistance becomes. Specifically, the filter was irradiated with light at a light intensity of 400 W/m² for 15 hours using a light-fading test machine (Sun Test CPS, manufactured by Atlas K.K.). The average light transmittance at a wavelength of 400 to 700 nm was measured from wavelength-light transmittance spectrum of the filter, which was measured before and after irradiation with light using a a spectrophotometer (“DU-640”, manufactured by Beckman Coulter, Inc.) and then the variation (difference) was calculated from the average light transmittance. The variation of the average light transmittance was calculated with respect to both of the UV-cut and non-UV-cut portions using a UV-cut filter (“L-38”, manufactured by HOYA Corporation. The results are shown in Table 1.

TABLE 1

Variation in average
transmittance at wavelength
of 400 to 700 nm before and
after irradiation with light

| | UV-cut | Non-UV-cut |
|---|---|---|
| Example 1 | 2.3% | 16.3% |
| Comparative | 9.1% | 17.2% |
| Example 1 | | |

As is apparent from the results shown in Table 1, light resistance of a filter can be improved by using an azo compound (I-1) in place of C.I. Solvent Yellow 162 which has conventionally been used.

The colored photosensitive composition of the present invention can be used to produce a color filter array to be formed on devices for coloration of solid image pickup devices.

The major embodiments and the preferred embodiments of the present invention are listed below.

[1] A colored photosensitive composition comprising a coloring agent, a photosensitive compound and an alkali-soluble resin, wherein

the coloring agent contains at least one selected from a red coloring agent, and a compound represented by the formula (I) and a salt thereof:

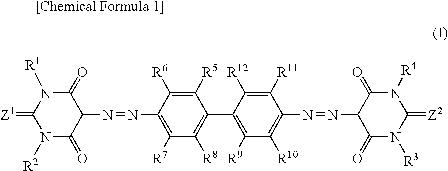

wherein in the formula (I), Z¹ and Z² each independently represents an oxygen atom or a sulfur atom;

R¹ to R⁴ each independently represents a hydrogen atom, a C₁₋₁₀ saturated aliphatic hydrocarbon group, a C₁₋₁₀ saturated aliphatic hydrocarbon group substituted with a hydroxyl group, a C₁₋₁₀ saturated aliphatic hydrocarbon group substituted with a C₁₋₈ alkoxyl group, a C₁₋₁₀ saturated aliphatic hydrocarbon group substituted with a C₁₋₈ thioalkoxyl group, an aryl group having 6 to 20 carbon atoms, an aralkyl group having 7 to 20 carbon atoms, or an acyl group having 2 to 10 carbon atoms; and

R⁵ to R¹² each independently represents a hydrogen atom, a halogen atom, a C₁₋₁₀ saturated aliphatic hydrocarbon group, a halogenated C₁₋₁₀ saturated aliphatic hydrocarbon group, a C₁₋₈ alkoxyl group, a carboxyl group, a sulfo group, a sulfamoyl group, or an N-substituted sulfamoyl group, and at least one of R⁵ to R¹² is an N-substituted sulfamoyl group.

[2] The colored photosensitive composition according to [1], wherein at least one of R⁵ to R⁸, and at least one of R⁹ to R¹² represent an N-substituted sulfamoyl groups.
[3] The colored photosensitive composition according to [2], wherein at least one of R⁵ and R⁸, and at least one of R⁹ and R¹² represent an N-substituted sulfamoyl group.
[4] The colored photosensitive composition according to any one of [1] to [3], wherein the N-substituted sulfamoyl group is a —SO₂NHR¹³ group, and R¹³ represents a C₁₋₁₀ saturated aliphatic hydrocarbon group, a C₁₋₁₀ saturated aliphatic hydrocarbon group substituted with a C₁₋₈ alkoxyl group, an aryl group having 6 to 20 carbon atoms, an aralkyl group having 7 to 20 carbon atoms, or an acyl group having 2 to 10 carbon atoms.
[5] The colored photosensitive composition according to any one of [1] to [4], wherein at least one of R¹ to R⁴ has 6 or more carbon atoms.
[6] The colored photosensitive composition according to [5], wherein at least one of R¹ to R⁴ is an aryl group having 6 to 20 carbon atoms.
[7] The colored photosensitive composition according to any one of [1] to [6], wherein the red coloring agent is a xanthene-based pigment.
[8] The colored photosensitive composition according to any one of [1] to [7], wherein the photosensitive compound is an oxime-based compound.
[9] The colored photosensitive composition according to any one of [1] to [8], wherein the content of the coloring agent is from 5 to 80 parts by mass based on 100 parts by mass of the total of the coloring agent, the photosensitive compound, and the alkali-soluble resin.
[10] The colored photosensitive composition according to any one of [1] to [9], wherein the content of the photosensitive compound is from 0.001 to 50 parts by mass based on 100 parts by mass of the total of the coloring agent, the photosensitive compound, and the alkali-soluble resin.
[11] The colored photosensitive composition according to any one of [1] to [10], wherein the content of the alkali-soluble resin is from 1 to 75 parts by mass based on 100 parts by mass of the total of the coloring agent, the photosensitive compound, and the alkali-soluble resin.
[12] The colored photosensitive composition according to any one of [1] to [11], further comprising a curing agent.
[13] A color filter array formed with the colored photosensitive composition according to any one of [1] to [12].
[14] A solid image pickup device comprising the color filter array according to [13].
[15] A camera system comprising the color filter array according to [13].

What is claimed is:

1. A colored photosensitive composition comprising a coloring agent, a photosensitive compound and an alkali-soluble resin, wherein
the coloring agent contains at least one selected from a red coloring agent, and a compound represented by the formula (I) and a salt thereof: 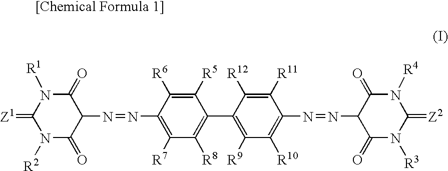
wherein in the formula (I), Z¹ and Z² each independently represents an oxygen atom or a sulfur atom;
R¹ to R⁴ each independently represents a hydrogen atom, a C₁₋₁₀ saturated aliphatic hydrocarbon group, a C₁₋₁₀ saturated aliphatic hydrocarbon group substituted with a hydroxyl group, a C₁₋₁₀ saturated aliphatic hydrocarbon group substituted with a C₁₋₈ alkoxyl group, a C₁₋₁₀ saturated aliphatic hydrocarbon group substituted with a C₁₋₈ thioalkoxyl group, an aryl group having 6 to 20 carbon atoms, an aralkyl group having 7 to 20 carbon atoms, or an acyl group having 2 to 10 carbon atoms; and
R⁵ to R¹² each independently represents a hydrogen atom, a halogen atom, a C₁₋₁₀ saturated aliphatic hydrocarbon group, a halogenated C₁₋₁₀ saturated aliphatic hydrocarbon group, a C₁₋₈ alkoxyl group, a carboxyl group, a sulfo group, a sulfamoyl group, or an N-substituted sulfamoyl group, and at least one of R⁵ to R¹² is an N-substituted sulfamoyl group.

2. The colored photosensitive composition according to claim 1, wherein at least one of R⁵ to R⁸, and at least one of R⁹ to R¹² represent an N-substituted sulfamoyl groups.

3. The colored photosensitive composition according to claim 2, wherein at least one of R⁵ and R⁸, and at least one of R⁹ and R¹² represent an N-substituted sulfamoyl group.

4. The colored photosensitive composition according to claim 1, wherein the N-substituted sulfamoyl group is a —SO₂NHR¹³ group, and R¹³ represents a C₁₋₁₀ saturated aliphatic hydrocarbon group, a C₁₋₁₀ saturated aliphatic hydrocarbon group substituted with a C₁₋₈ alkoxyl group, an aryl group having 6 to 20 carbon atoms, an aralkyl group having 7 to 20 carbon atoms, or an acyl group having 2 to 10 carbon atoms.

5. The colored photosensitive composition according to claim 1, wherein at least one of R¹ to R⁴ has 6 or more carbon atoms.

6. The colored photosensitive composition according to claim 5, wherein at least one of R¹ to R⁴ is an aryl group having 6 to 20 carbon atoms.

7. The colored photosensitive composition according to claim 1, wherein the red coloring agent is a xanthene-based pigment.

8. The colored photosensitive composition according to claim 1, wherein the photosensitive compound is an oxime-based compound.

9. The colored photosensitive composition according to claim 1, wherein the content of the coloring agent is from 5 to 80 parts by mass based on 100 parts by mass of the total of the coloring agent, the photosensitive compound, and the alkali-soluble resin.

10. The colored photosensitive composition according to claim 1, wherein the content of the photosensitive compound is from 0.001 to 50 parts by mass based on 100 parts by mass of the total of the coloring agent, the photosensitive compound, and the alkali-soluble resin.

11. The colored photosensitive composition according to claim 1, wherein the content of the alkali-soluble resin is from 1 to 75 parts by mass based on 100 parts by mass of the total of the coloring agent, the photosensitive compound, and the alkali-soluble resin.

12. The colored photosensitive composition according to claim 1, further comprising a curing agent.

13. A color filter array formed with the colored photosensitive composition according to claim 1.

14. A solid image pickup device comprising the color filter array according to claim 13.

15. A camera system comprising the color filter array according to claim 13.
